(19) United States
(12) Patent Application Publication
(10) Pub. No.: US 2023/0244901 A1
(43) Pub. Date: Aug. 3, 2023

(54) COMPUTE-IN-MEMORY SRAM USING MEMORY-IMMERSED DATA CONVERSION AND MULTIPLICATION-FREE OPERATORS

(71) Applicant: THE BOARD OF TRUSTEES OF THE UNIVERSITY OF ILLINOIS, URBANA, IL (US)

(72) Inventors: Amit Ranjan Trivedi, Urbana, IL (US); Shamma Nasrin, Urbana, IL (US); Priyesh Shukla, Urbana, IL (US); Nastaran Darabi, Urbana, IL (US); Maeesha Binte Hashem, Urbana, IL (US); Ahmet Enis Cetin, Urbana, IL (US)

(21) Appl. No.: 18/161,830

(22) Filed: Jan. 30, 2023

Related U.S. Application Data
(60) Provisional application No. 63/304,265, filed on Jan. 28, 2022.

(51) Int. Cl. G06N 3/02

(52) U.S. Cl. CPC G06N 3/02

(57) ABSTRACT

In accordance with the principles herein, a co-design approach for compute-in-memory inference for deep neural networks (DNN) is set forth. Multiplication-free function approximators are employed along with a co-adapted processing array and compute flow. Resulting methods, systems, devices, and algorithms in accordance with the principles herein overcome many deficiencies in the currently available in—methods, systems, devices, and algorithms (in-SRAM) DNN processing devices. Systems, devices, and algorithms constructed in accordance with the co-adapted implementation herein seamlessly extends to multi-bit precision weights, eliminates the need for DACs, and easily extends to higher vector-scale parallelism. Additionally, a SRAM-immersed successive approximation ADC (SA-ADC) can be constructed, where the parasitic capacitance of bit lines of SRAM array can be exploited as a capacitive DAC. The dominant area overhead in SA-ADC, due to its capacitive DAC, can allow low area implementation of within-SRAM SA-ADC.

### CROSS-REFERENCE TO RELATED APPLICATIONS

This application claims the benefit of U.S. Provisional Application No. 63/304,265 filed Jan. 28, 2022, and incorporated herein by reference in the entirety.

### STATEMENT OF GOVERNMENT INTEREST

This invention was made with government support under NSF 2046435 awarded by the National Science Foundation. The government has certain rights in the invention.

### TECHNICAL FIELD

The present disclosure relates to deep neural networks. More specifically, the disclosure relates to a co-design approach for compute-in-memory, associated methods, systems, devices, and algorithms.

### BACKGROUND

In many practical known applications, deep neural networks (DNNs) have shown a remarkable prediction accuracy. DNNs in these applications typically utilize thousands to millions of parameters (i.e., weights) and are trained over a huge number of example patterns. Operating over such a large parametric space, which is carefully orchestrated over multiple abstraction levels (i.e., hidden layers), facilitates DNNs with a superior generalization and learning capacity, but also presents critical inference constraints, especially when considering real-time and/or low power applications. For instance, when DNNs are mapped on a traditional computing engine, the inference performance is strangled by extensive memory accesses, and the high performance of the processing engine helps little.

A radical approach, gaining attention to address this performance challenge of DNN, is to design memory units that not only store DNN weights but also using them against inputs to locally process DNN layers. Therefore, using such ‘compute-in-memory’ (CIM) high volume data traffic between processor and memory units is obviated, and the critical bottleneck can be alleviated. Moreover, a mixed-signal in-memory processing of DNN operands reduces necessary operations for DNN inference. For example, using charge/current-based representation of the operands, the accumulation of products simply reduces to current/charge summation over a wire. Therefore, dedicated modules and operation cycles for product summations are not necessary.

In recent years, several compute-in-static random-access memory (in-SRAM) DNN implementations have been shown. However, many critical limitations remain, which inhibit the scalability of the processing. In FIG. 1, convolution computation static random-access memory (CONV-SRAM) as a motivating example, however, the challenges are common to most other designs and in-SRAM applications too. To compute the inner product of l-element weight (w) and input (x) vectors, l-digital-to-analog converters (l-DACs) and one analog-to-digital converter (ADC) are required. Since DACs are concurrently active, they lead to both high area and power. With the increasing precision of operands, the design of DACs also becomes more complex. For example, time-domain DACs have been used to handle this complexity; however, with increasing input precision, either operating time increases exponentially, or complex analog domain voltage scaling is necessitated. In other systems, DACs are obviated, but the operation is limited to binary inputs and weights, which has low accuracy.

An analog-to-digital converter (ADC) is needed to digitize the inner product of w and x vectors in FIG. 1. If x is n-bit and ADC combine the output of l cells, the minimum necessary precision of the ADC is n+log 2(l) to avoid any quantization loss. Therefore, ADC precision requirement becomes more stringent with increasing input precision and the number of cells being summed. Moreover, scaled technology nodes of SRAM precludes analog-heavy ADCs embedded within SRAM. In another system, a charge sharing-based ADC was integrated with SRAM.

However, the worst-case comparison steps grow exponentially with ADC's precision, limiting vector scale parallelism (i.e., the number of cells/products l that can be processed concurrently). In another known system, ADC is avoided by using a comparator circuit, but this limits the implementation only to step function-based activation and does not support the mapping of DNNs with larger weight matrices that cannot fit within an SRAM array. Near-memory processing avoids the complexity of ADC/DAC by operating in the digital domain only. The schemes use the time-domain and frequency-domain summing of weight-input products. Unlike charge/current-based sum, however, time/frequency-domain summation is not instantaneous.

A counter or memory delay line (MDL) can be used to accumulate weight-input products. With increasing vector-scale parallelism (length of input/weight vector l), the integration time of counter/MDL increases exponentially, which again limits parallelism and throughput. Thus, the known systems fail to provide a scalable solution for efficient DNN processing.

Since a DNN typically requires thousands to millions of parameters to achieve higher predictive capacity, a key challenge for employing DNNs in low power/real-time application platforms is its excessively high workload. Furthermore, typical digital computing platforms may have separate units for storage and computing. Therefore, the foremost challenge for digital processing of DNNs is due to excessive bandwidth demand between storage and computing. Processing of DNNs with accuracy and significantly reduced area and power overheads is needed.

### SUMMARY

In accordance with the principles herein, a co-design approach for compute-in-memory (CIM) inference for deep neural networks (DNN) is set forth. Multiplication-free function approximators, based on l1 norm, are employed along with a co-adapted processing array and compute flow. Resulting methods, systems, devices, and algorithms in accordance with the principles herein overcome many deficiencies in the currently available compute-in-static random-access memory (in-SRAM) DNN processing devices. Systems, devices, and algorithms constructed in accordance with the co-adapted implementation herein seamlessly extends to multi-bit precision weights, eliminates the need for DACs, and easily extends to higher vector-scale parallelism. Additionally, a SRAM-immersed successive approximation-based analog-to-digital converter (SA-ADC) can be constructed, where the parasitic capacitance of bit lines of SRAM array can be exploited as a capacitive DAC. And particularly for SA-ADC.

The dominant area overhead in SA-ADC comes, due to its capacitive DAC, by exploiting the intrinsic parasitic of SRAM array systems according to the principles herein and can allow low area implementation of within-SRAM SA-ADC. For example, a SRAM can be configured to improve in-SRAM processing in DNN systems can comprise digital to analog converter (DAC)-free compute-in-memory units and processing cycles.

A SRAM can be configured to improve in-SRAM processing in DNN systems can comprise SRAM-immersed analog to digital converter (ADC) that obviate the need for a dedicated ADC primitive.

For either of these SRAMS, a SRAM can be further defined by 8×62 SRAM requiring 5-bit ADC, configured to achieve approx. 105 tera operations per second per Watt Topps/W with 8-bit input/weight processing at 45 nm CMOS.

Alternatively, for either of these SRAMS, a SRAM can be further defined by 8×30 SRAM macro requiring 4-bit ADC configured to achieve approx. 84 TOPS/W.

Thus, systems herein can achieve A DAC-free SRAM configured to both store DNN weights and locally process mixed DNN layers to reduce traffic between processor and memory units. In one example a bit plane-wise DAC-free within SRAM processing is achieved wherein each SRAM cell only performs 1-bit logic operation and SRAM outputs are integrated over time for multibit operations. Such a system can use charge/current representation of the operands to reduce the computation to charge/current summation over a wire, to eliminate the need for dedicated modules and operation cycles for product summations.

SRAM arrays and interfaces herein can be configured to map DNNs with large weight matrices, such as in the order of megabytes.

SRAMs can include a correlation operator configured to multiply a one-bit element sign(x) against full precision weight (w), and one-bit sign (w) against (x) to avoid direct multiplication between full precision variables while processing at least one of binary DNN layers and mixed DNN layers. The correlation operator can facilitate processing within a single product port of SRAM cells, thus reducing dynamic energy of the system. The SRAM can be configured for single-ended processing. The SRAM can be configured to facilitate time-domain and frequency domain summing of weight-input products.

A SRAM can comprise: a first array half; and a second array half, wherein bit lines in the first array half compute weight-input correlation and bit lines in the second array half process binary search of SA-ADC to digitize the correlation output.

Also, a DNN operator can be configured to perform compute-in-SRAM operations, including multi-bit precision DNN while also reducing precision demands on ADC's located in the system.

Other exemplary embodiments consistent with the principles herein are contemplated as well. The attributes and advantages will be further understood and appreciated with reference to the accompanying drawings. The described embodiments are to be considered in all respects only as illustrative and not restrictive, and the scope is not limited to the foregoing description. Those of skill in the art will recognize changes, substitutions and other modifications that will nonetheless come within the scope and range of the claims.

### BRIEF DESCRIPTION OF THE DRAWINGS

The preferred embodiments are described in conjunction with the attached figures.

FIG. 1 illustrates a high-level overview of in-SRAM processing in the current art and key limitations.

FIG. 2A illustrates an exemplary embodiment of compute-in-SRAM macro for multiplication-free operator-based DNN inference.

FIG. 2B illustrates an exemplary embodiment of a 8T SRAM cell for in-memory processing.

FIG. 2C illustrates an input/weight mapping to SRAM macro and operation sequence.

FIG. 2D illustrates instruction cycles for in-SRAM processing.

FIG. 2E illustrates instruction cycles for the data conversion consisting of precharge, average, compare, and SAR steps.

FIG. 3 illustrates a cross-coupled comparator schematic.

FIG. 4 illustrates an overview of integration of μArrays and μChannels to an array manager.

FIG. 5 illustrates utilization of parasitic capacitance of the product lines for the DAC implementation.

FIG. 6A illustrates a chart of MAV output levels that vary due to process variability in PL capacitors.

FIG. 6B illustrates μArray columns with extremely varying PL capacitor that are discarded by padding them with memory and column entries that doesn't contribute to the MAV numerator.

FIG. 6C illustrates an on-chip estimation scheme to estimate PL columns with extremely varying capacitance.

FIG. 6D illustrates MAV crossover probability at varying PL capacitor mismatch and μArray sizes and mitigating MAV crossover probability by discarding columns with high PL capacitor variability.

FIG. 6E illustrates estimating comparator's variability by forcing it to metastable point and calibrating tail currents to mitigate process variability.

FIG. 7 illustrates a static random-access memory (SRAM)-based compute-in-memory (CIM) macro integrating storage and Bayesian inference (BI) with the inset figure highlighting 8T SRAM cell with storage and product ports and CIM embedded with random dropout bit generator for MC-Dropout inference.

FIG. 8 illustrates a SRAM-embedded random dropout bit generator.

FIG. 9 illustrates a dropout probability calibration.

FIG. 10 illustrates a SRAM-immersed analog-to-digital converter.

FIG. 11 shows the implementation of logic operations for compute reuse.

### DESCRIPTION

Several exemplary embodiments are set forth herein and illustrate configurations and devices in accordance with the principles herein. Other system configurations, devices and components are contemplated as well.

The present disclosure relates to deep neural networks. More specifically, the disclosure relates to a co-design approach for compute-in-memory, associated methods, systems, devices, and algorithms.

A multiplication-free neural network operator is used that eliminates high-precision multiplications in input-weight correlation. In the operator, the correlation of weight w and input x is represented as:

w⊕x=Σᵢ sign(xᵢ)·abs(wᵢ)+sign(wᵢ)·abs(xᵢ) Equation (1)

wherein · is an element-wise multiplication operator, + is an element-wise addition operator, Σ is a vector sum operator, sign( ) operator is ±1 and abs( ) operator produces an absolute unsigned value of the operand w or the operand x.

In Equation (1), the correlation operator is inherently designed to only multiply a one-bit element of sign(x) against full precision w, and one-bit sign(w) against x. By avoiding direct multiplications between full precision variables, DACs can be avoided in in-memory computing.

Equation (1) may be reformulated to minimize the dynamic energy of computation and is represented by:

sign(wᵢ)·abs(xᵢ)=2×Σᵢ step(wᵢ)·abs(xᵢ)−Σᵢ abs(xᵢ) Equation (2a)

sign(xᵢ)·abs(wᵢ)=2×Σᵢ step(xᵢ)·abs(wᵢ)−Σᵢ abs(wᵢ) Equation (2b)

with “step( )·abs( )” representing low dynamic energy, “abs(x)” representing shared computation, and “abs(w)” representing weight statistics.

In the reformulation, step( )∈[0, 1]. The reformulation allows processing with single product port of SRAM cells; thus, reducing dynamic energy. This can be compared to current implementations where operations with weights w∈[−1, 1] require product accumulation over both bit lines. While current SRAM may be 10T to support differential ended processing, here SRAM is 8T due to single-ended processing.

However, the above reformulation also has residue terms Σᵢ abs(xᵢ) and Σᵢ abs(wᵢ). The first term can be computed using a dummy row of weights, all storing ones. For a given input, this computation is referenced for all weight vectors; thus, computing overheads amortize. The second term is a weight statistic that can be pre-computed and can be looked-up during evaluation.

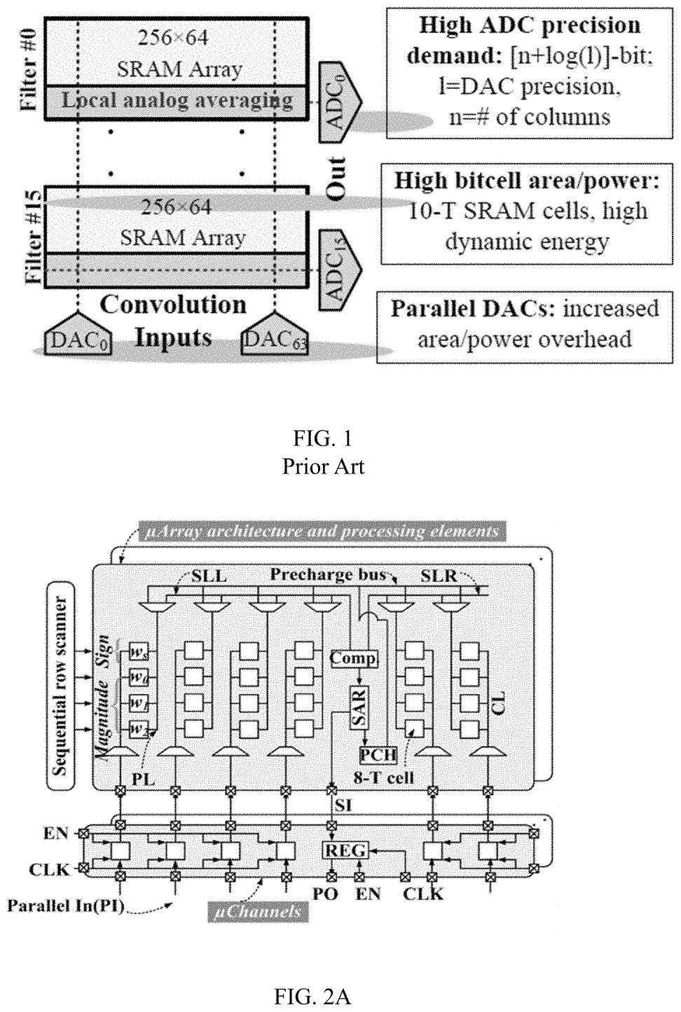

Also contemplated is parasitic capacitance of bit lines of SRAM array can be exploited as a capacitive digital-to-analog converter (DAC) for successive approximation-based ADC (SA-ADC). In the architecture, when bit lines in one half of the array compute the weight-input correlation, bit lines in the other half implement binary search of SA-ADC to digitize the correlation output. Remarkably, the DNN operator also helps reducing precision constraints on SA-ADC. With the operator, each SRAM cell only performs 1-bit logic operation; thus, to digitize the output of l columns, ADC with log 2(l) precision is needed. Compare this to CONV-SRAM in FIG. 1, where necessary ADC's precision is n+log₂(l) since each SRAM cell processes n-bit DAC's output. By simplifying data converters, the scheme can also achieve higher vector-scale parallelism, i.e., allows processing a higher number of parallel columns (l) with the same ADC complexity as CONV-SRAM.

Now, the co-adapted multiplication-free operator for the in-SRAM dep neural network is introduced. The potential of multiplication-free DNN operators is expanded to considerably reduce the complexity of SRAM-based compute-in-memory design. The operator is adjusted with abs( ) on operands w and x in Equation (1) to further simplify compute-in-memory processing steps. The adjusted operator also achieves high prediction accuracy on various benchmark datasets. Note that a multiplication-free operator in Equation (1) is based on the [symbol] ₁ norm, since x⊕x=2∥x∥₁. In traditional neural networks, neurons perform inner products to compute the correlation between the input vector with the weights of the neuron. A new neuron is defined by replacing the affine transform of a traditional neuron using co-designed NN operator as ϕ(α(z⊕w)+b) where w∈R^{d}, α, b∈R are weights, the scaling coefficient, and the bias, respectively.

Moreover, since the NN operator is nonlinear itself, an additional nonlinear activation layer (e.g., ReLU) is not needed, i.e., ϕ( ) can be an identity function. Most neural network structures including multi-layer perceptrons (MLP), recurrent neural networks (RNN), and convolutional neural networks (CNN) can be easily converted into such a compute-in-memory compatible network structures by just replacing ordinary neurons with the activation functions defined using ⊕ operations without modification of the topology and the general structure.

The co-designed neural network can be trained using standard back-propagation and related optimization algorithms. The back-propagation algorithm computes derivatives with respect to the current values of parameters. However, the key training complexity for the operator is that the derivative of α(x⊕w)+b with respect to x and w is undefined when xᵢ and wᵢ are zero. The partial derivative of x⊕w with respect to x and w can be expressed:

$$\frac{\partial ( x ⊕ w )}{\partial {x}_{i}} = sign ( {w}_{i} ) sign ( {x}_{i} ) + 2 \times abs ( {w}_{i} ) δ ( {x}_{i} ) \qquad Equation ( 3 a )$$

$$\frac{\partial ( x ⊕ w )}{\partial {w}_{i}} = sign ( {x}_{i} ) sign ( {w}_{i} ) + 2 \times abs ( {x}_{i} ) δ ( {w}_{i} ) \qquad Equation ( 3 b )$$

Here, δ( ) is a Dirac-delta function. For gradient-descent steps, the discontinuity of sign function can be approximated by a steep hyperbolic tangent and the discontinuity of Dirac-delta function can be approximated by a steep zero-centered Gaussian function.

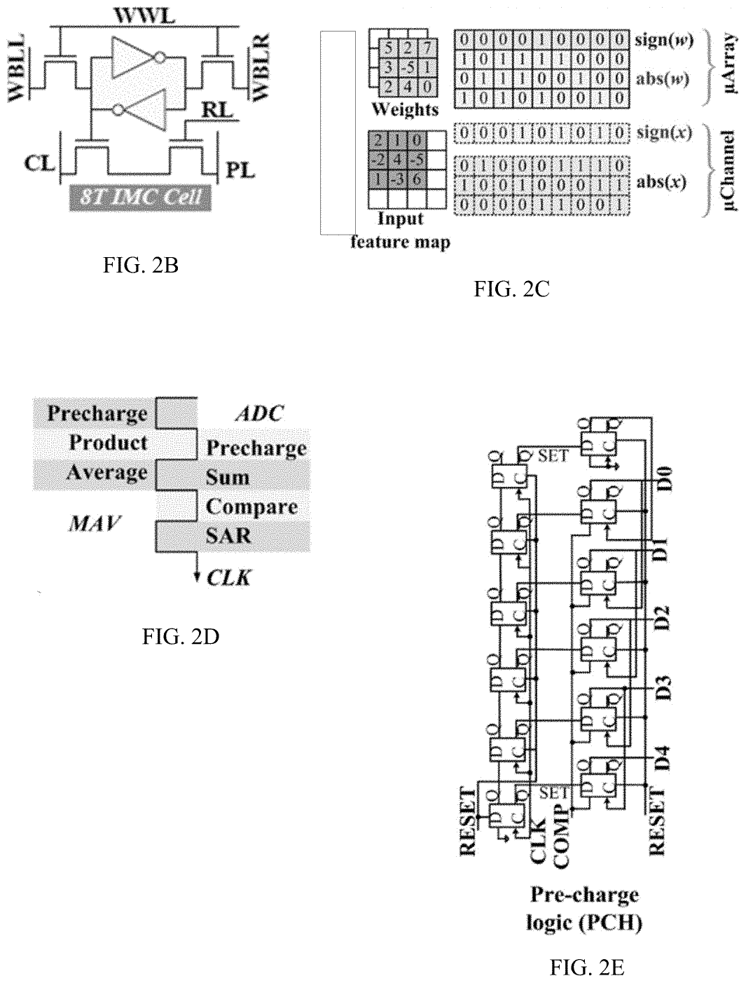

In one embodiment of a compute-in-SRAM macro based on multiplication-free operator is now described in which a compute-in-SRAM macro is based on μArrays and μChannels. FIG. 2A shows the design of compute-in-SRAM macro for multiplication-free operator-based DNN inference. In the design, an SRAM macro consists of μArrays and μChannels, as shown. Each μArray is dedicated to storing one weight channel. DNN weights are arranged across columns in a μArray where each bit plane of weights is arranged in a row. Therefore, an N-dimensional weight channel with m-bit precision weights will require m rows and N columns of SRAM cells in a μArray.

FIG. 2B shows the 8T SRAM cell used for the in—SRAM processing of the operator. Extra transistors in the cell compared to a 6T cell decouple typical read/write operations to within cell product. The added transistors are selected by the row and column select lines (RL and CL) and operate on the product bit line (PL). The decoupling of read/write and product operations mitigates interference between the operations, reduces the impact of process variability, and allows operation in storage hold mode.

Each μArray is augmented with a μChannel. μChannels convey digital inputs/outputs to/from μArrays. μChannels are essentially low overhead serial-in serial-out digital paths based on scan-registers. If a weight filter has many channels, μChannels also allow stitching of μArrays so that inputs can be shared among the μArrays. If two columns are merged, inputs are passed to the top array directly from the bottom array, and the loading of input bits is bypassed on the top column; therefore, overheads to load input feature-map are minimized. FIG. 2C illustrates input/weight mapping to SRAM macro and operation sequence. For step(x)·abs(w) step in w x, step(x) vector is loaded on the μChannel and operated against abs(w) rows of μArray. For step(w)abs(x), bit planes of abs(x) vector are sequentially loaded on the μChannel and operated against step(w) row of the μArray.

In a μArray, to compute x⊕w, the operation proceeds by bit planes. If the left half computes the weight-input product, the right half digitizes. Both halves subsequently exchange their operating mode to process weights stored in the right half. When evaluating the inner product terms step(x)abs(w), computations for i^{th} weight vector bit plane are performed in one instruction cycle. At the start, the inverted logic values of step(x) bit vector are applied to CL through μChannels. PL is precharged. When clock switches, tri-state MUXes float PL. Compute-in-memory controller activates SRAM rows storing i^{th} bit vector of w. In a column j, only if both w_{j,i} and step(xⱼ) are one, the corresponding PL segment discharges. To minimize the leakage power, SRAM cells are maintained in their hold mode and dedicate additional clock time to discharge PLs. The potential of all column lines is averaged on the sum-lines to determine the net multiply-average (MAV), i.e.,

$$\sum \frac{1}{N} ( {w}_{j , i} \times step ( {x}_{j} ) )$$

for input vector and weight bit plane wⱼ. FIG. 2D shows the instruction sequence for the left half to compute MAV consisting of precharge, product, and average stages.

Since MAV output at the sum line (SL) is charge-based, an analog-to-digital converter (ADC) is necessary to convert the output into digital bits. In FIG. 2A, the right half of the array implements an SRAM-immersed successive approximation (SA) data converter to digitize the output at the left sum line (SLL). Reference voltages for SA-based data conversion are generated by exploiting PL parasitic in the right half.

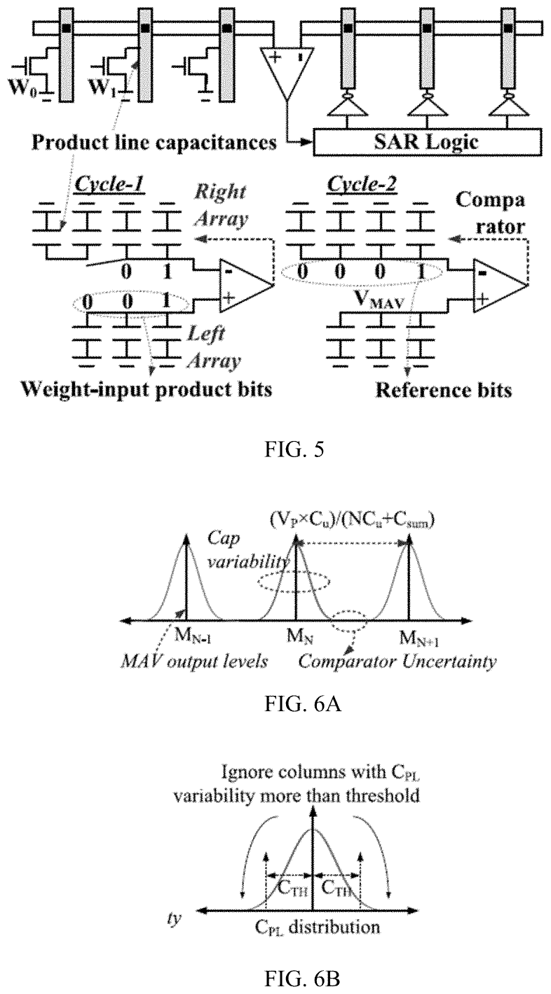

FIG. 5 describes the utilization of parasitic capacitance of the product lines for the DAC implementation of SA-ADC. The product lines of the right half are charged and discharged according to the SAR logic to produce the reference voltage at the right sum line (SLR). In the i^{th} SA iteration, 2ⁱ capacitors are used to generate the reference voltage. Each half also uses a dummy PL of matching capacitance to complete SA. In FIG. 5 the left most capacitor in the right half is indicating the matching dummy PL capacitance. Although the capacitance of SL affects the MAV range, its effect nullifies during the digitization since the capacitor is a common mode to both ends of the comparator. Nonetheless, limited voltage swing range due to SL's capacitance limits the number of parallel columns in a μArray that can be reliably operated.

FIG. 2E also shows the instruction cycles for the data conversion consisting of precharge, average, compare, and SAR steps. One cycle of data conversion lasts two clock periods. For n-bit digitization, 2n clock cycles are needed. In a conversion cycle, at the start, PLs in the right half are charged based on initialization or SA output from the previous cycle. At the next clock transition, PLs are merged to average their voltage. Next, a comparator compares the potential at the left and right sum lines (SLL and SLR in FIG. 2A). Subsequently, SA logic operates on the comparator's output to update the digitization registers and produces the next precharge logic bits.

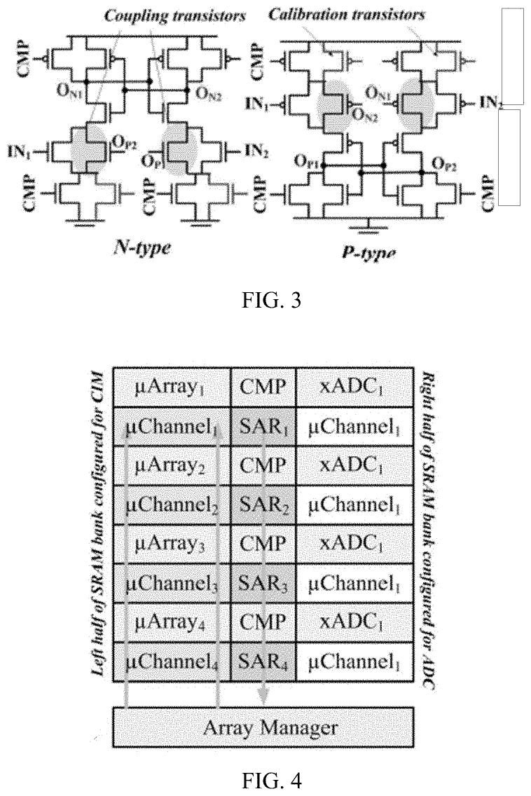

The comparator in the design must accommodate rail-to-rail input voltages at SLL and SLR. Therefore, as shown in FIG. 3, a cross-coupled comparator is used consisting of n-type and p-type modules. The n-type module receives inputs at NMOS transistors while p-type receives at PMOS. Coupling transistors to integrate both modules are highlighted in FIG. 3. If the input voltages are closer to zero, the p-type instance dominates. Otherwise, if the input voltages are close to VDD, the n-type instance dominates. Connections to coupling transistors in the figure ensure that n-type or p-type instances can be overridden at the appropriate voltage range.

FIG. 4 shows the integration of μArrays with an array manager that handles the loading of input features maps (IFMaps) and reading of μArray outputs. In FIG. 4, each μArray has an associated μChannel, which assists in such interfacing with the array manager. When the left halves of μArrays compute the scalar product of input and weight bits, the right halves of μArrays are utilized for SRAM-immersed ADC, as discussed above.

An array manager inserts the address of the μArray where the IFMap data needs to be transmitted. 2D and 3D filters are flattened to one-dimensional representation to feed columns of μArray in parallel. Based on the μArray address, associated D flip-flops in the μChannel receive data from the array manager in parallel. The array manager scans μChannels sequentially, feeding IFMap data in turn to each. For a read scheme by the array manager, at the end of the Successive Approximation Register (SAR) operation cycle, digitized input-weight dot product bits are stored on SAR registers. To read the output data, the array manager inserts the SAR unit's address to the decoder. Based on the unit's address, its respective data is read.

According to one embodiment, loading of IFMap data to a μArray requires one clock cycle, after which the μArray stays busy for 2n+2 clock cycles to compute the scalar product and digitize it. Here, n is the precision of SRAM-immersed ADC.

At the end of each processing cycle, the digitized output is read from the SAR registers associated with the μArray. The two components of MF-operator are computed in turn. Array manager stores IFMaps collected from the centralized control unit (CCU). CCU also programs a state machine in the array manager that dictates the loading sequence of IFMap bits to μChannels. IFMap loading sequence depends on DNN specifications, such as the number of parallel channels. Array manager also controls the order in which various rows in a μArray are activated for step(x) abs(w), step(w) abs(x) operations. Array manager also post-processes outputs from μArrays. According to the reformulation in Equations (2a) and (2b), the dot product step(x) abs(w) must be scaled by two before being combined with Σ abs(wᵢ). For such post-processing, the array manager comprises an adder and shifter unit.

The multiplication-free inference framework using compute-in-SRAM μArrays and μChannels has many key advantages over the competitive designs. First, a multiplication-free learning operator obviates digital-to-analog converters (DAC) in SRAM macros. Meanwhile, DACs incur considerable area/power in the current competitive designs. Although overheads of DAC can be amortized by operating in parallel over many channels, the emerging trends on neural architectures, such as depth-wise convolutions in MobileNets, show that these opportunities may diminish. Comparatively, the present DAC-free framework is much more efficient in handling even thin convolution layers by eliminating DACs; thereby, allowing fine-grained embedding of μChannels without considerable overheads. If the filter has many parallel channels, this architecture can also exploit input reuse opportunities by merging μChannels as discussed above.

Secondly, a multiplication-free operator, is also synergistic with the discussed bit plane-wise processing. Bit plane-wise processing followed in this work reduces the ADC's precision demand in each cycle by limiting the dynamic range of MAV. Note that with bit plane-wise processing, for n column lines, MAV varies over 2nd levels. However, if such bit plane-wise processing is performed for the typical operator, an excessive O(n²) operating cycles will be needed for n-bit precision. Meanwhile, a multiplication-free operator only requires O(2n) cycle. Lastly, unique opportunities to exploit SRAM array parasitic for SRAM-immersed ADC are set forth herein. The system, methods, devices, and algorithms configured to be processed by system components herein obviate a major area overhead currently required for SA-ADC processing. Therefore, the exemplary compute-in-SRAM macro herein can maintain a high memory density.

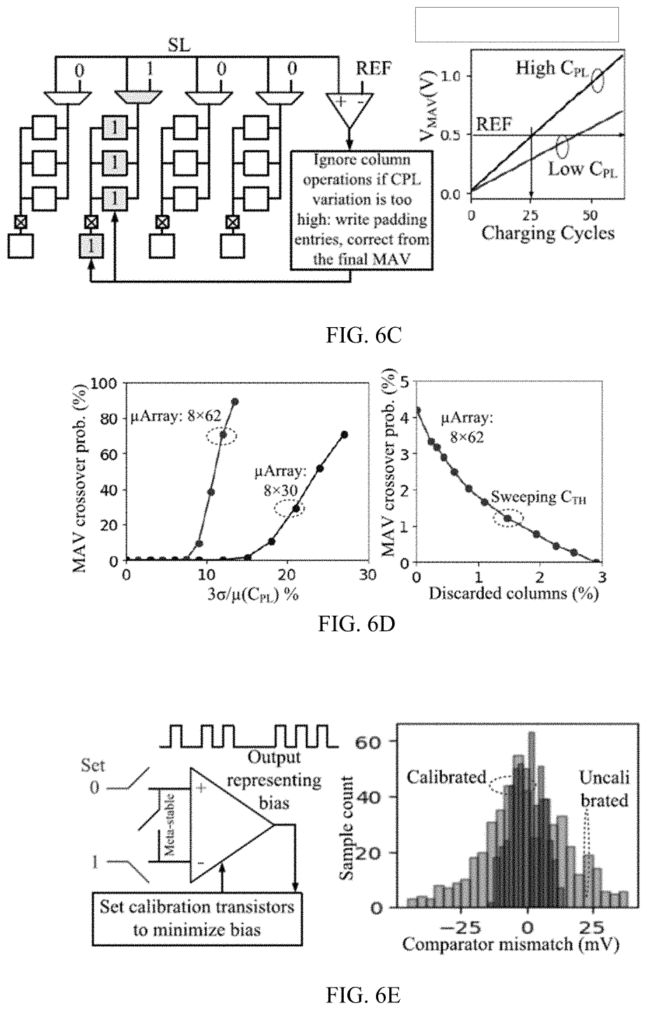

Impact of process variability and on-chip calibration is now discussed. In FIG. 6A, due to process variability among PL capacitors, MAV output levels will follow a Gaussian distribution. The distribution of MAV output levels arises both due to variability in PL capacitors as well as many combinations to obtain a MAV level. If MAV output levels crossover, the weight-input product from μArrays can be erroneous. In accordance with the principles herein, the accuracy of MAVs is mainly affected by the PL capacitor's mismatch. The effect of global variability among PL capacitors cancels out by bi-partitioning a μArray—generating MAVs in one half and reference voltages in the other half so that the global variability of PL capacitors becomes common mode. Considering a Gaussian distribution of MAV output levels, FIG. 6D shows the probability of MAV crossover (PF) in a μArray at varying capacitor mismatch and μarray size. PF increases with higher PL capacitor variability as well as with the increasing number of columns in a μArray. Therefore, the maximum number of columns in a μArray (i.e., its parallelism) is constrained.

FIG. 6C is directed to an on-chip scheme to self-determine the usable column width of a μArray based on its process variability. In the figure, the strength of a PL capacitor is measured on-chip by repeatedly charging the sum-line through it and counting the number of cycles to cross a set threshold. A smaller PL capacitor will require more charging cycles to cross the threshold. Most extreme PL capacitors are identified. If their process variability is more than an acceptable margin, these columns are not used [FIG. 6B]. In accordance with the principles herein, adding a switch to disconnect such columns is avoided, since it will considerably increase the area overhead of the on-chip calibration scheme. Note that the column disconnects switch and a memory cell to store the switch enable needs to be implemented for each column of μArray. Instead, the effect of columns with extreme C_{PL} variation is lessened by writing one to all SRAM cells in the column and by applying the CL input signal to be one. Therefore, the column with extremely varying C_{PL} always discharges and only contributes to the charge averaging step. The sensitivity of extremely varying C_{PL} to MAV is thereby low since it only contributes to the denominator of MAV, where its effect averages out against other columns in μArray. Based on this scheme, the right of FIG. 6D shows the MAV cross-over probability for 8×62 μArrays considering 12% mismatch among PL capacitors and at varying C_{TH} levels [FIG. 8(b)]. By discarding only about 3% of columns, MAV cross-over probability can be sufficiently suppressed.

Similarly, process variability in the comparator constraints the minimum pre-charge voltage and the maximum number of columns in a μArray. In FIG. 6E, an on-chip calibration scheme is used to mitigate the comparator's process variability. The scheme selects N- and P-type counterparts of the comparator in turn. The comparator is first set to a known initial condition and then forced to a metastable point by shorting both inputs. By repeatedly resetting and setting the comparator, its bias can be estimated from the output bit sequence. An unbiased comparator should have an equal probability of 0/1 under thermal noise. The tail currents in the left and right half of the comparator can be adjusted to minimize the comparator's bias. Calibrating transistors for the comparator are shown in FIG. 2A. A counter monitors the comparator's output and adds calibration transistors to the left or right half to minimize bias in the comparator. In the right of FIG. 6E, using a 2-bit calibration, the comparator's mismatch can be reduced to ±12 mV from the initial ±45 mV.

Compute-in-memory offers immense energy efficiency benefits over digital by eliminating weight movements. Mixed-signal processing of compute-in-memory also obviates processing overheads for adders by exploiting physics (Kirchoff s law) to sum the operands over a wire. Note that additions are a significant portion of the total workload in a digital DNN inference. However, compute-in-memory is also inherently limited to only weight stationary processing. The advantages of stationary weight processing reduce if the filter has fewer channels or if the input has smaller dimensions. Compute-in-memory is also more area expensive compared to digital processing, which can leverage denser memory modules such as DRAM. On the other hand, the memory cells in compute-in-memory are larger to support both storage and computations within the same physical structure. Additionally, multibit precision DNN inference is complex using compute-in-memory.

Therefore, many prior works utilize binary-weighted neural networks, which, however, constraints the learning space and reduces the prediction accuracy. Deep in-memory architecture (DIMA) considers multibit precision in-memory inference; however, the implementation suffers from an exponential reduction in the throughput with increasing precision.

Meanwhile, the critical area and efficiency challenge is overcome using devices and systems herein, wherein a co-design approach by adapting the DNN operator to in-memory processing constraints. According to the multiplication-free compute-in-memory framework herein, the parametric learning space expands, yet the implementation complexities are equivalent to a binarized neural network. Even so, the accuracy of multiplication-free operators is somewhat lower than the typical deep learning operator due to the non-differentiability of gradients.

Considering the above trade-offs, the key to balance scalability with energy efficiency in DNN inference is through a synergistic integration of compute-in-memory with digital processing. According to one embodiment, as the processing propagates through the networks, weights per layer increase, but the number of operations per weight reduces. This is, in fact, typical to any DNN due to shrinking input feature map dimensions, which reduces the weight reuse opportunities.

Since the starting layers have fewer parameters but much higher weight reuse, they are quite suited for compute-in-memory. The latter layers require many more parameters but have low weight reuse. Therefore, digital processing can minimize the excessive storage overheads of these layers with denser storage.

Using this strategy, a mixed mapping configuration that layer-wise combines compute-in-memory and digital processing is contemplated. For example, in the mixed implementation of MobileNetV2, feature extraction layers with high weight reuse are mapped in compute-in-memory using an 8-bit multiplication-free operator. Regression layers and others with low weight reuse are mapped in digital using the typical operator. Remarkably, based on the synergistic mapping strategy, compute-in-memory only stores about a third of the total weights; yet, performs more than 85% of the total operations. Therefore, the synergistic mapping can optimally translate compute-in-memory's energy-efficiency advantages to the overall system-level efficiency, and yet, limits its area overheads.

The synergistic mapping also improves the prediction accuracy, since only critical layers are implemented with the energy-expensive typical operator while the remaining most of the network is operated with multiplication-free operators. In one embodiment that considers MNIST and CIFAR10 prediction networks, the average macro-level energy efficiency is predicted in TOPs/W. For digital processing, 2.8 TOPs/W may be used.

A compute-in-SRAM macro based on a multiplication-free learning operator is set forth. The macro comprises low area/power overhead μArrays and μChannels. Operations in the macro are DAC-free. μArrays exploit bit line parasitic for low overhead memory-immersed data conversion. The configuration accuracy of on MNIST, CIFAR10, and CIFAR100 data sets. On an equivalent network configuration, it may be shown that the framework has 1.8× lower error on MNIST and 1.5× lower error on CIFAR10 compared to the binarized neural network. At 8-bit precision, a 8×62 compute-in-SRAM μArray achieves ˜105 TOPS/W, which is significantly better than the current compute-in-SRAM designs at matching precision. The platform herein also offers several runtime control-knobs to dynamically trade-off accuracy, energy, and latency. For example, weight precision can be dynamically modulated to reduce prediction latency, and ADC's precision can be controlled to reduce energy. Additionally, for deeper neural networks, mapping configurations using high weight reuse layers can be implemented in the compute-in-SRAM framework, and parameter-intensive layers (such as fully connected) can be implemented through digital accelerators. The synergistic mapping strategy combining both multiplication-free and typical operator achieves both high-energy efficiency and area efficiency in operating deeper neural networks.

An 8×62 SRAM macro herein, which requires a 5-bit ADC, can achieve 105 tera operations per second per Watt (TOPS/W) with 8-bit input/weight processing at 45 nm CMOS. An 8×30 SRAM macro herein, which requires a 4-bit ADC, can achieve 84 TOPS/W. SRAM macros that require lower ADC precision are more tolerant of process variability, however, have lower TOPS/W as well. The accuracy and performance of the network herein was evaluated for MNIST, CIFAR10, and CIFAR100 datasets. A network configuration which adaptively mixes multiplication-free and regular operators was selected. The network configurations utilize the multiplication-free operator for more than 85% operations from the total. The selected configurations are 98.6% accurate for MNIST, 90.2% for CIFAR10, and 66.9% for CIFAR100. Other configurations are contemplated as well. Since most of the operations in the considered configurations are based on SRAM macros, the compute-in-memory's efficiency benefits broadly translate to the system-level.

Additional information including accuracy on benchmark datasets, power performance including dynamic precision and scaling may be found in MF Net: Compute-In-Memory SRAM for Multibit Precision Inference Using Memory-Immersed Data Conversion and Multiplication-Free Operators, Nasrin et al., IEEE Transactions on Circuits and Systems I: Regular Papers, Volume 68, Issue 5, May 2021 and Compute-in-Memory Upside Down: A Deep Learning Operator Co-Design Perspective, Nasrin et al., 2021 Design, Automation & Test in Europe Conference & Exhibition, Feb. 1-5, 2021.

The invention is discussed now with respect to a particular embodiment directed to compute-in-memory (CIM) with Monte Carlo (MC) dropouts for Bayesian edge intelligence. Unlike classical inference where the network parameters such as layer-weights are learned deterministically, Bayesian inference learns them statistically to express model's uncertainty along with the prediction itself.

Using Bayesian inference, prediction confidence can be systematically accounted in decision making and risk-prone actions can be averted when the prediction confidence is low. Nonetheless, Bayesian inference of deep learning models is also considerably more demanding than classical inference. To reduce the computational workload of Bayesian inference, efficient approximately are used, e.g., variational inference. Variational inference reduces the learning and inference complexities of fully-fledged Bayesian inference by approximating weight uncertainties using parametric distributions. The predictive robustness of MC-Dropout-based variational inference for robust edge intelligence using MC-CIM is provided.

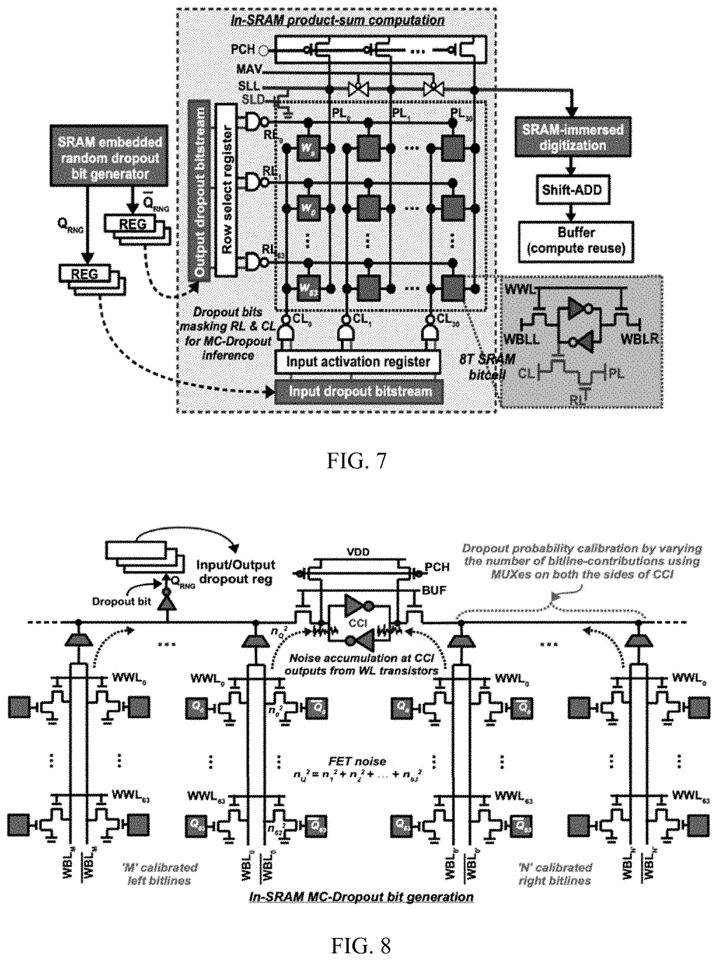

FIG. 7 illustrates a static random-access memory (SRAM)-based CIM macro integrating storage and Bayesian inference (BI) with the inset figure highlighting 8T SRAM cell with storage and product ports and CIM embedded with random dropout bit generator for MC-Dropout inference.

Specifically, FIG. 7 shows the baseline CIM macro architecture using eight transistor static random-access memory (8T-SRAM). The inset in FIG. 7 shows an 8T-SRAM cell with various access ports for write and CIM operations. The write word line (WWL) selects a cell for write operation and the data bit is written through the left and right write bit lines (WBLL and WBLR). During inference, input bit is applied to cell using the column-line (CL) port and output is evaluated on the product-line (PL). The row line (RL) connects the bit cells horizontally to select weight bits in the respective row for within-memory inference. The CIM array operates in a bit plane-wise manner directly on the digital inputs to avoid digital-to-analog converters (DACs). Bit plane of like-significance input and weight vectors are processed in one cycle as shown in FIG. 2(d). Since the 8-T SRAM cell has decoupled ports for inference and storage, in-SRAM inference doesn't impinge on read stability. Thus, memory transistors can be optimally sized to mitigate area concerns at edge platforms.

The operation within the CIM module in FIG. 7 begins with precharging PL and applying input at CL in the first half of a clock cycle. In the next half of a clock cycle, RL is activated to compute the product bit on PL port. PL discharges only when input and stored bit are both one.

The output of all PL ports is averaged on the sum line (SLL) using transmission gates, determining the net multiply-average (MAV) of bit plane-wise input and weight vector. The charge-based output at SLL is passed to SRAM immersed analog-to-digital converter (xADC), supra.

xADC operates using successive approximation register (SAR) logic and essentially exploits the parasitic bit line capacitance of a neighboring CIM array for reference voltage generation. In the consecutive clock cycles different combinations of input and weight bit planes are processed and the corresponding product-sum bits are combined using a digital shift-ADD. xADC's convergence cycles are uniquely adapted by exploiting the statistics of MAV leading to a considerable improvement in its time and energy efficiency.

In FIG. 7, to support random input dropouts, inputs to CL peripherals are ANDed with a dropout bitstream. Likewise, for random output dropouts, row activations are masked by ANDing RL signals with output dropout bitstream. Therefore, inference in MC-Dropout requires an additional processing step of dropout bit generation for each applied input vector. High-speed generation of dropout bit vectors is thereby a critical overhead for CIM-based MC-Dropout.

Note that each weight-input correlation cycle for a CIM-optimal inference operator (⊕) lasts 2(n−1) clock periods for n-bit precision weights and inputs. Therefore, for m-column CIM array, a throughput of

$$\frac{m}{2 ( n - 1 )}$$

random bits/clock is needed. Meeting this requirement,

$$⌈ \frac{m}{2 ( n - 1 )} ⌉$$

parallel CCI-based RNGs are embedded in a CIM array, each capable to generate a dropout bit per clock period. CCI-based dropout vector generation is pipelined with CIM's weight-input correlation computations, i.e., when CIM array processes an input vector frame, memory-embedded RNGs sample dropout bits for the next frame.

FIG. 8 illustrates a SRAM-embedded random dropout bit generator (RNG). SRAM's write parasitic are exploited for RNG calibration. During inference, write wordlines (WWL) to a CIM macro are deactivated. Therefore, along a column, each write port injects leakage and noise current to the bit line as shown in FIG. 8. Even though the leakage current from each port, I_{leak,ij}, varies under threshold voltage (V_{TH}) mismatches, the accumulation of leakage current from parallel ports reduces the sensitivity of net leakage current at the bit lines, i.e., ΣᵢI_{leak,ij} shows less sensitivity to V_{TH} mismatches. Each write port also contributes noise current, I_{noi,ij}, to the bit line. Since the noise current from each port varies independently, the net noise current, ⊖ᵢI_{noi,ij} magnifies. Such filtering is exploited of process-induced mismatches and magnification of noise sources at the bit lines for RNG's calibration.

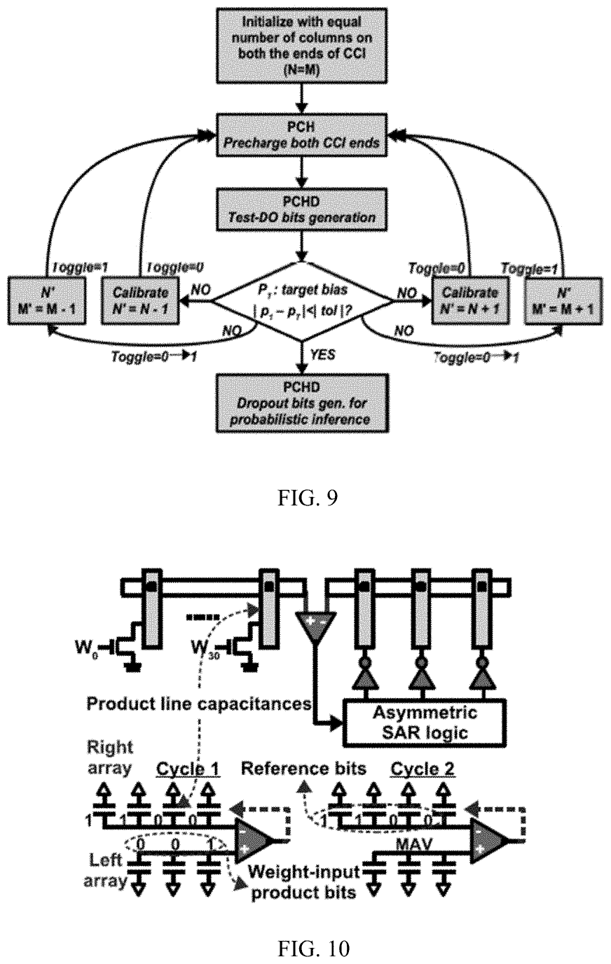

An equal number of SRAM columns are connected to both ends of CCI. Both bit lines (BL and B̅L̅) of a column are connected to the same end to cancel out the effect of column data. Both ends of CCI are precharged using PCH signal and then let discharged using column-wise leakage currents for half a clock cycle. At the clock transition, pulldown transistors are activated using a delayed PCH (PCHD) to generate the dropout bit. For the calibration, CCI generates a fixed number of output random bits serially from where its bias may be estimated. A simple dropout probability calibration scheme in FIG. 9 then adapts the parallel columns connected to each end until CCI meets the desired dropout bias within the tolerance. The operation of CCI-based dropout generation can be further improved using fine-grained calibration along with the coarse-grained calibration.

The probabilistic activation of inputs in MC-Dropout can also be exploited to adapt the digitization of multiply average voltage (MAV) generated at the sum line (SLL). By exploiting the statistics of MAV, time efficiency of digitization may improve.

FIG. 10 illustrates a SRAM-immersed analog-to-digital converter. In FIG. 10, bit line capacitance of a neighboring CIM array is exploited in xADC to realize the capacitive DAC for SA, thereby, averting a dedicated DAC and corresponding overhead. While xADC may follow a typical binary search of a conventional data converter, it may also follow an asymmetric successive approximation. The digitization cycles for MAV may be minimized using asymmetric approximation. For this, reference levels at each cycle are selected based on the MAV statistics such that they iso-partition the distribution segment being approximated by the conversion cycle. For example, in the first cycle, the first reference point R₀ is follows mean(MAV), instead of half of Vₘₐₓ where Vₘₐₓ is the maximum voltage generated at sum line (SLL). Likewise, in the next iteration, reference levels R₀₀ and R₀₁ are generated to iso-partition MAV distribution falling between [0, R₀] and [R₀, Vₘₐₓ], respectively. Since asymmetric SA may result in unbalanced search of references, very few cases require more SA cycles than in conventional SA-ADC, and for the majority of inputs, the total searches are much less.

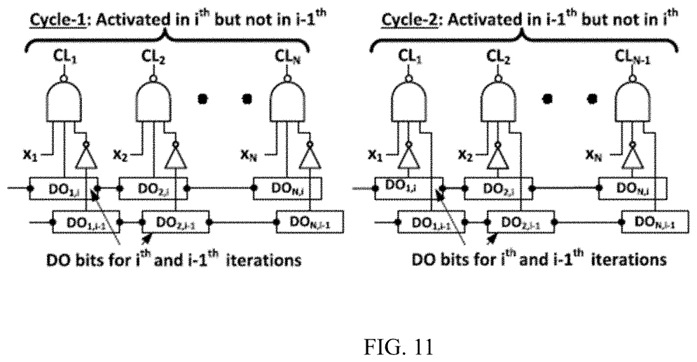

FIG. 11 shows the implementation of logic operations for compute reuse. At each iteration, computations are performed in two cycles. In the first, cycle-1, only those activations that are present in i^{th} iteration but not in i−1^{th} are processed. While in second, cycle-2, activations that are present in i−1^{th} iteration but not in i^{th} are processed. The selection of non-overlapping activations can be made by retaining dropout bits for the previous iteration and using simple logic operations as shown in FIG. 11.

The compute-reuse method is applicable for MC-Dropout inference procedures when only one layer is subjected to probabilistic inference while the other layers operate through classical deterministic inference. Although in its most general case, MC-Dropout inference can be applied on all layers of a DNN by considering the dropout probability, for example to be 0.5, the procedure may be performed on the layer just before final regression—classification output performs optimally.

When a dropout procedure is applied on all layers, the prediction accuracy on the considered visual odometry application degrades. Even more, since the probability of dropout bits in a layer can itself be learned (i.e., need not be 0.5 or same as used during the training), it is possible to minimize the energy and latency overhead of Bayesian edge intelligence by limiting dropout iterations to only one layer and learning the probability parameters using variational inference procedures. Note that making only the last layer of a classical deep neural network, generative or Bayesian techniques may be explored in many other works and settings, including for example, autonomous navigation and gene sequencing.

Additional information on data flow optimization as well as information on power performance, an confidence-aware inference may be found in MC-CIM: Compute-in-Memory With Monte-Carlo Dropouts for Bayesian Edge Intelligence, Priyesh Shukla et al., IEEE Transactions on Circuits and Systems I: Regular Papers, Volume 70, Issue 2, February 2023.

The compute-in-memory framework may be used for probabilistic inference targeting edge platforms that not only gives prediction but also the confidence of prediction. This is crucial for risk-aware applications such as drone autonomy and augmented/virtual reality. For Monte Carlo Dropout (MC-Dropout)-based probabilistic inference, Monte Carlo compute-in-memory (MC-CIM) is embedded with dropout bits generation and optimized computing flow to minimize the workload and data movements. Energy savings is benefitted significantly even with additional probabilistic primitives in CIM framework. Implications on non-idealities in MC-CIM on probabilistic inference shows promising robustness of the framework for many applications including, for example, mis-oriented handwritten digit recognition and confidence-aware visual odometry in drones.

While the disclosure is susceptible to various modifications and alternative forms, specific exemplary embodiments have been shown by way of example in the drawings and have been described in detail. It should be understood, however, that there is no intent to limit the disclosure to the embodiments disclosed, but on the contrary, the intention is to cover all modifications, equivalents, and alternatives falling within the scope of the disclosure as defined by the appended claims.

1. A Static Random-Access Memory (SRAM) device configured to improve in-SRAM processing in deep neural network (DNN) systems by eliminating one or more digital to analog converters (DACs), the SRAM device comprising:
a deep neural network (DNN) operator that eliminates multiplication processes in a correlation of a weight (w) and an input (x).

2. The SRAM device according to claim 1 wherein the DNN operator is:
$$w ⊕ x = {\sum }_{i} sign ( {x}_{i} ) \cdot abs ( {w}_{i} ) + sign ( {w}_{i} ) \cdot abs ( {x}_{i} )$$
wherein · is an element-wise multiplication operator, + is an element-wise addition operator, Σ is a vector sum operator, sign( ) operator is ±1 and abs( ) operator produces an absolute unsigned value of the operand w or the operand x.

3. The SRAM device according to claim 1 wherein the DNN operator performs the steps of multiplying one-bit sign(x) against higher precision abs(w), and one-bit sign(w) against higher precision abs(x).

4. The SRAM device according to claim 1, wherein the DNN operator reduces dynamic energy and is represented by:
$${\sum }_{i} sign ( {w}_{i} ) \cdot abs ( {x}_{i} ) = 2 \times {\sum }_{i} step ( {w}_{i} ) \cdot abs ( {x}_{i} ) - {\sum }_{i} abs ( {x}_{i} ) \\ {\sum }_{i} sign ( {x}_{i} ) \cdot abs ( {w}_{i} ) = 2 \times {\sum }_{i} step ( {x}_{i} ) \cdot abs ( {w}_{i} ) - {\sum }_{i} abs ( {w}_{i} ) .$$

5. The SRAM device according to claim 1 further comprising an analog to digital converter (ADC) that obviates the need for a dedicated ADC primitive.

6. The SRAM device according to claim 1 configured to both store DNN weights and locally process mixed DNN layers to reduce traffic between a processor and memory units.

7. The SRAM device according to claim 1 defined by an array of cells, wherein each cell only performs a 1-bit logic operation, and a plurality of outputs are integrated over time for multibit operations.

8. The SRAM device according to claim 1 further comprising a charge/current representation of the operands to reduce the computation to charge/current summation over a wire, to eliminate the need for dedicated modules and operation cycles for product summations.

9. The SRAM device according to claim 7, wherein the array is configured to map one or more DNNs with one or more weight matrices in the order of megabytes.

10. The SRAM device of claim 1 configured for single-ended processing.

11. The SRAM device of claim 1 configured to facilitate time-domain and frequency domain summing of weight-input products.

12. The SRAM device according to claim 7, wherein the array comprises:
a first array half; and
a second array half, wherein bit lines in the first array half compute weight-input correlation and bit lines in the second array half process binary search of successive approximation-based analog-to-digital converter (SA-ADC) to digitize the correlation output.

13. The SRAM device according to claim 1, wherein the SRAM is an 8×62 SRAM requiring 5-bit ADC, configured to achieve approx. 105 tera operations per second per Watt Topps/W with 8 bit input/weight processing at 45 nm CMOS.

14. The SRAM device according to claim 1, wherein the SRAM is an 8×30 SRAM macro requiring 4 bit ADC configured to achieve approx. 84 TOPS/W.

15. A process performed by a Static Random-Access Memory (SRAM) device, the process configured to improve processing in deep neural network (DNN) systems, the process including instructions for performing by the SRAM the steps of:
eliminating one or more digital to analog converters; and
multiplying a one-bit element sign(x) against a full precision weight (w), and a one-bit sign(w) against an input (x) to avoid direct multiplication between full precision variables while performing step of processing at least one of binary DNN layers and mixed DNN layers.

16. The process according to claim 15, wherein further comprising the step of processing within a single product port of SRAM cells, thus reducing dynamic energy of the system.

17. The process according to claim 16, wherein the process configured for single-ended processing.

18. The process according to claim 17 further comprising the step of summing of weight-input products in both time-domain and frequency domain.

19. A static random-access memory (SRAM) comprising:
a first array half; and
a second array half, wherein bit lines in the first array half compute a weight-input correlation and bit lines in the second array half processes a binary search to digitize a correlation output.

20. The SRAM according to claim 19, wherein the binary search is a successive approximation-based analog-to-digital converter (SA-ADC).
